(19) United States
(12) Patent Application Publication
(10) Pub. No.: US 2015/0104630 A1
(43) Pub. Date: Apr. 16, 2015

(54) PREPREG FOR PRINTED CIRCUIT BOARD, MANUFACTURING METHOD THEREOF, AND PRINTED CIRCUIT BOARD INCLUDING THE SAME

(71) Applicant: Samsung Electro-Mechanics Co., Ltd., Suwon-si (KR)

(72) Inventors: Jin Seok Moon, Suwon-si (KR); Sa Yong Lee, Suwon-si (KR); Keun Yong Lee, Suwon-si (KR); Seong Hyun Yoo, Suwon-si (KR)

(73) Assignee: Samsung Electro-Mechanics Co., Ltd., Suwon-si (KR)

(21) Appl. No.: 14/149,567

(22) Filed: Jan. 7, 2014

(30) Foreign Application Priority Data
Oct. 10, 2013 (KR) 10-2013-0120777

(51) Int. Cl. H05K 1/03; B32B 38/10; B32B 38/08; H05K 3/00; B32B 37/24

(52) U.S. Cl. CPC H05K 1/0366; H05K 3/007; B32B 37/24; B32B 38/08; B32B 38/10; B32B 2037/243; B32B 2457/08
USPC 428/220; 428/426; 156/247

(57) ABSTRACT

Disclosed herein are a prepreg for a printed circuit board, a manufacturing method thereof, and a printed circuit board including the same. More particularly, the manufacturing method of a prepreg for a printed circuit board includes: coating an insulating composition on each of the two carrier films to form an insulating layer and drying the coated insulating composition to form first and second carrier substrates; disposing glass fiber between the insulating layers of the first and second carrier substrates and bonding the first and second carrier substrates to each other to form a laminated substrate; pressing the laminated substrate; and removing the carrier film from the laminated substrate subjected to the pressing.

The prepreg may be manufactured so as to have the desired thickness or maintain a uniform thickness, such that thickness quality may be stabilized, and a coefficient of thermal expansion property may be improved.

### CROSS REFERENCE TO RELATED APPLICATION

This application claims the benefit of Korean Patent Application No. 10-2013-0120777, filed on Oct. 10, 2013, entitled “Prepreg for Printed Circuit Board, Manufacturing Method thereof, and Printed Circuit Board Including the Same”, which is hereby incorporated by reference in its entirety into this application.

### BACKGROUND OF THE INVENTION

1. Technical Field

The present invention relates to a prepreg for a printed circuit board, a manufacturing method thereof, and a printed circuit board including the same.

2. Description of the Related Art

In accordance with the development of electronic devices, a printed circuit board has gradually become light, thin, and miniaturized. In order to satisfy these demands, a wiring of the printed circuit board has become more complicated and highly densified. Electric, thermal, and mechanical properties required in the board as described above are important factors.

Particularly, in accordance with the trend toward miniaturization and high performance of the electronic devices, in a multi-layer printed circuit board, high density, high function, miniaturization, thinness, and the like, are required. Therefore, as a printed circuit board in which various electronic components are mounted has also been thinned and highly integrated, the printed circuit board has been gradually finely patterned.

The printed circuit board is configured of copper mainly serving as circuit wiring and a polymer serving as an interlayer insulating material. In the polymer configuring an insulating layer as compared with copper, various properties, such as a coefficient of thermal expansion, a glass transition temperature, thickness-uniformity, and the like, are required. Particularly, the insulating layer should be manufactured so as to have a thinner thickness.

However, as the circuit board becomes thin, a thickness quality of the board may be unstable, such that properties such as the coefficient of thermal expansion (CTE), a dielectric constant, a dielectric loss, or the like, may be deteriorated, and a warpage phenomenon at the time of mounting the components and a signal transmission defect in a high frequency region may be generated. Further, in the case of manufacturing a prepreg using an impregnation method according to the prior art, there is a limitation in thinning the prepreg, and there are problems in that a thickness is not constantly maintained, and it is impossible to manufacture an asymmetric prepreg.

### SUMMARY OF THE INVENTION

In the present invention, a fact that in a manufacturing method of a prepreg for a printed circuit board, the thickness of the prepreg for a printed circuit board may be adjusted and thinned and a CTE property may be improved was confirmed, and the present invention was completed based on the fact as described above.

The present invention has been made in an effort to provide a manufacturing method of a prepreg for a printed circuit board capable of adjusting an impregnation position of glass fiber.

In addition, the present invention has been made in an effort to provide a prepreg for a printed circuit board capable of being thinned and having an improved CTE property using the manufacturing method of a prepreg for a printed circuit board.

Further, the present invention has been made in an effort to provide a printed circuit board having an improved CTE property using the prepreg.

According to a preferred embodiment of the present invention, there is provided a manufacturing method of a prepreg for a printed circuit board, the manufacturing method including: coating an insulating composition on each of the two carrier films to form an insulating layer and drying the coated insulating composition to form first and second carrier substrates; disposing glass fiber between the insulating layers of the first and second carrier substrates and bonding the first and second carrier substrates to each other to form a laminated substrate; pressing the laminated substrate; and removing the carrier film from the laminated substrate subjected to the pressing.

The insulating composition may contain bismaleimide, a 4-functional bisphenol F type epoxy resin, and a liquid crystal oligomer.

The insulating composition may contain 10 to 30 weight % of the liquid crystal oligomer, 5 to 20 weight % of bismaleimide, and 5 to 20 weight % of the 4-functional bisphenol F type epoxy resin.

The liquid crystal oligomer may be represented by the following Chemical Formula 1.

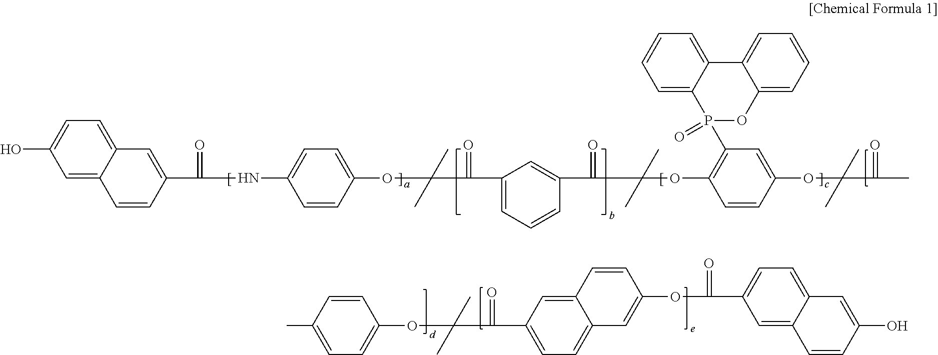

Where, a is an integer of 13 to 26, b is an integer of 13 to 26, c is an integer of 9 to 21, d is an integer of 10 to 30, and e is an integer of 10 to 30.

The 4-functional bisphenol F type epoxy resin may be N,N,N′,N′-tetraglycidyl-4,4′-methylene bisbenzenamine represented by the following Chemical Formula 2.

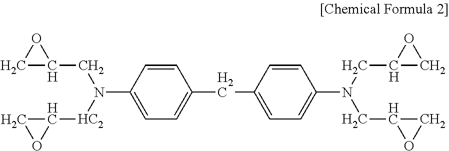

The bismaleimide resin may be an oligomer of phenyl methane maleimide represented by the following Chemical Formula 3.

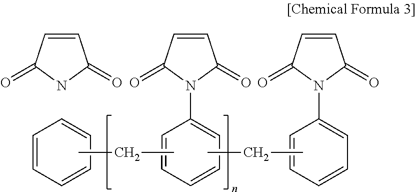

Where, n is an integer of 1 or 2.

The insulating composition may further contain an inorganic filler, a curing agent, a curing accelerator, and an initiator.

The inorganic filler may be contained at a content of 50 to 80 weight % based on 100 weight % of the insulating composition and be one of silica (SiO₂), alumina (Al₂O₃), silicon carbide (SiC), barium sulfate (BaSO₄), talc, mica powder, aluminum hydroxide (AlOH₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃), calcium zirconate (CaZrO₃), and a combination thereof.

The curing agent may be contained at a content of 0.05 to 0.2 weight % based on 100 weight % of the resin composition and be at least one selected from an amine based curing agent, an acid anhydride based curing agent, a polyamine curing agent, a polysulfide curing agent, a phenol novolac type curing agent, a bisphenol A type curing agent, and dicyandiamide curing agent.

The liquid crystal oligomer may have a number average molecular weight of 3000 to 6000.

The carrier film may be made of any one selected from Teflon, polyimide, polyethylene terephthalate (PET), and a combination thereof.

The first and second insulating layers may be formed by performing the coating at least two times on the carrier film by any one method selected from a spray coating method, a dip coating method, a spin coating method, and a gravure coating method.

In the drying of the insulating composition, the insulating composition may be dried at 10 to 150° C. for 3 to 180 minutes.

The insulating layer may include: a first insulating layer formed on the first carrier substrate; and a second insulating layer formed on the second carrier substrate, wherein the first and second insulating layers have thicknesses equal to or different from each other.

The glass fiber may be at least one selected from a group consisting of E-glass fiber, T-glass fiber, U-glass fiber, quarts fiber textiles, and aramid fiber textiles.

In the pressing the laminated substrate, the laminated substrate may be pressed at 10⁻⁵ to 15 torr and 10 to 250° C. for 10 seconds to 5 hours.

The pressing of the laminated substrate may be performed by any one method of a batch method and a roll press method.

In the pressing of the laminated substrate, the laminated substrate may be pressed at a surface pressure of 0.1 to 50 MPa.

In the pressing of the laminated substrate, the laminated substrate may be pressed at a nip pressure of 1 to 500 kgf/cm.

According to another preferred embodiment of the present invention, there is provided a prepreg for a printed circuit board manufactured by the manufacturing method as described above.

The prepreg for a printed circuit board may have a thickness of 10 to 200 μm.

The prepreg for a printed circuit board may have a coefficient of thermal expansion of 9 to 12 ppm/° C.

According to another preferred embodiment of the present invention, there is provided a printed circuit board including: the prepreg manufactured as described above; and a buildup layer formed on an insulating layer of the prepreg.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a flow chart showing a manufacturing method of a prepreg for a printed circuit board according to a preferred embodiment of the present invention;

FIGS. 2A to 2F are process views showing the manufacturing method of a prepreg for a printed circuit board according to the preferred embodiment of the present invention; and

FIG. 3 is a cross-sectional view showing a printed circuit board including a prepreg according to another preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

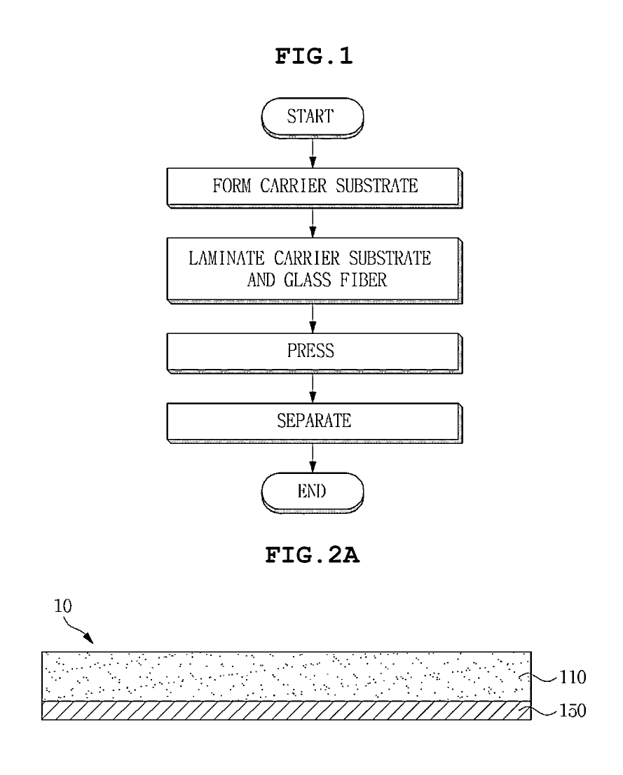

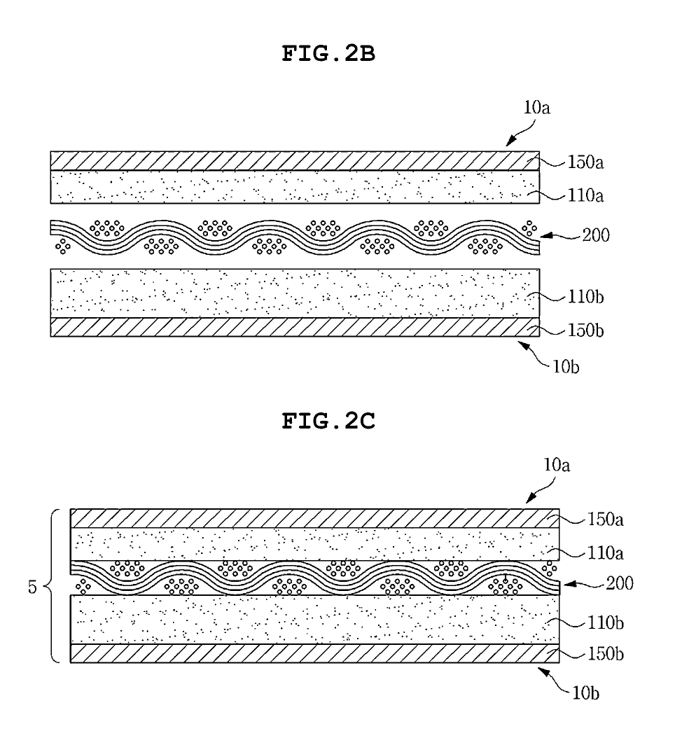

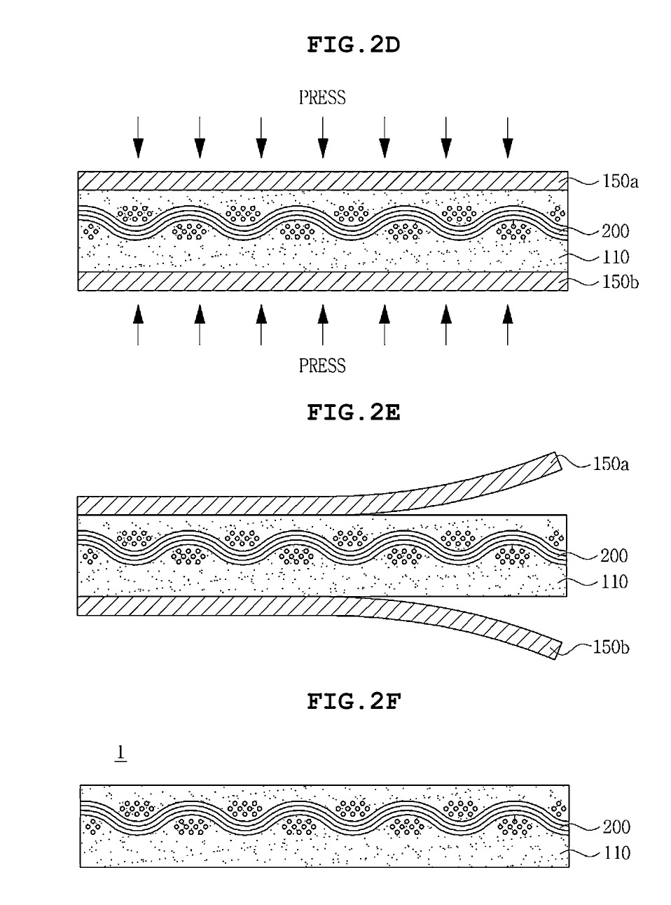

FIG. 1 is a flow chart showing a manufacturing method of a prepreg for a printed circuit board according to a preferred embodiment of the present invention, and FIGS. 2A to 2F are process views showing the manufacturing method of a prepreg for a printed circuit board according to the preferred embodiment of the present invention.

Referring to FIGS. 1 and 2A, a carrier substrate 10 including an insulating layer 110 may be formed by coating an insulating composition onto each of the two carrier films 150 to form the insulating layer 110 and drying the insulating composition onto the carrier film 150.

Here, the insulating composition contains bismaleimide, a 4-functional bisphenol F type epoxy resin, and a liquid crystal oligomer. More specifically, the insulating composition may contain 10 to 30 weight % of the liquid crystal oligomer, 5 to 20 weight % of bismaleimide, and 5 to 20 weight % of the 4-functional bisphenol F type epoxy resin.

The liquid crystal oligomer may include a liquid crystal oligomer of which hydroxyl groups are introduced at both ends, represented by the following Chemical Formula 1.

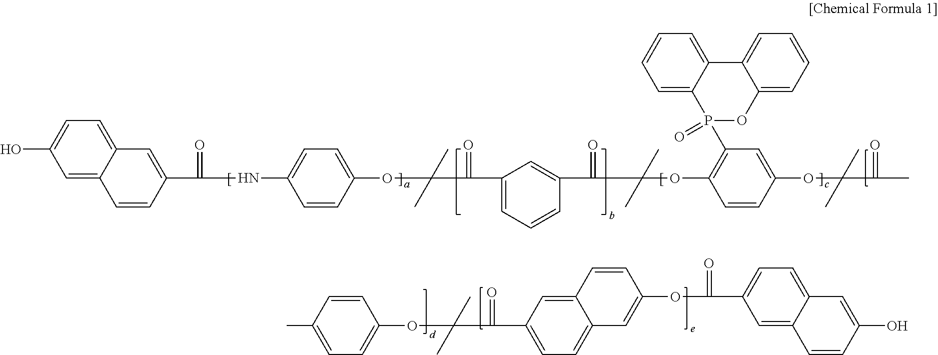

where, a is an integer of 13 to 26, b is an integer of 13 to 26, c is an integer of 9 to 21, d is an integer of 10 to 30, and e is an integer of 10 to 30.

A use amount of the liquid crystal oligomer is not particularly limited, but may be preferably 10 to 30 weight %. In the case in which the use amount is less than 10 weight %, a decrease in a coefficient of thermal expansion (CTE) and improvement of a glass transition temperature may be insignificant, and in the case in which the use amount is more than 30 weight %, mechanical properties may be deteriorated.

The liquid crystal oligomer may have a number average molecular weight of preferably 2500 to 6,500 g/mol, more preferably 3000 to 5,500 g/mol, and most preferably 3500 to 5,000 g/mol. In the case in which the number average molecular weight of the liquid crystal oligomer is less than 2,500 g/mol, the mechanical properties may be weak, and in the case in which the number average molecular weight is more than 6,500 g/mol, solubility may be decreased.

A viscosity of the liquid crystal oligomer may be preferably 500 to 1500 cps, most preferably 800 to 1000 cps. In the case in which the viscosity of the liquid crystal oligomer is less than 500 cps, handling of the liquid crystal oligomer is not easy, and in the case in which the viscosity is more than 1500 cps, formability may be deteriorated.

In addition, the insulating composition according to the preferred embodiment of the present invention may contain the 4-functional bisphenol F type epoxy resin. The epoxy resin may be N,N,N′,N′-tetraglycidyl-4,4′-methylene bisbenzenamine in which 4-functional groups are introduced, represented by the following Chemical Formula 2.

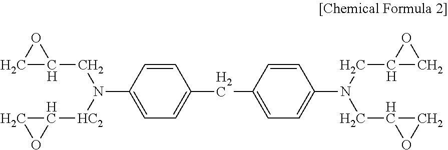

The epoxy based resin represented by Chemical Formula 2 may be N,N,N′,N′-tetraglycidyl-4,4′-methylene bisbenzenamine having 4-functional groups introduced therein.

A use amount of the epoxy based resin represented by Chemical Formula 2 is not particularly limited, but may be preferably 5 to 20 weight %. In the case in which the use amount is less than 5 weight %, a decrease in a coefficient of thermal expansion (CTE) may be insignificant, and in the case in which the use amount is more than 20 weight %, mechanical properties may be deteriorated. Further, an epoxy based resin having a viscosity of 20000 cps may be used.

The liquid crystal oligomer and the epoxy based resin are mixed with N,N′-dimethylaceteamide (DMAc) at a predetermined mixing ratio together with dicyandiamide, thereby forming the composition. In this composition, in order to carry out a cure reaction with the liquid crystal oligomer in which the hydroxyl group is introduced, N,N,N′,N′-tetraglycidyl-4,4′-methylenebisbenzenamine, which is an epoxy based resin, is added thereto to thereby be thermally cured. In this case, the coefficient of thermal expansion (CTE) that is important to material properties of a circuit board, may be decreased due to flexibility of a molecular chain between a hydroxyl group and epoxy based resin generated while being reacted with the multi-functional epoxy resin.

The insulating composition according to the preferred embodiment of the present invention may contain a bismaleimide resin in order to improve heat resistance in the insulating composition. The bismaleimide resin is an oligomer of phenyl methane maleimide represented by the following Chemical Formula 3.

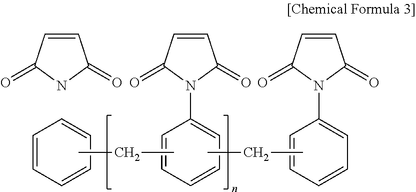

Where, n is an integer of 1 or 2.

A use amount of the oligomer of phenyl methane maleimide is not particularly limited, but may be preferably 5 to 20 weight %. In the case in which the use amount is less than 5 weight %, the glass transition temperature may not be improved, and in the case in which the use amount is more than 20 weight %, brittleness may be increased, such that it may be difficult to manufacture a product using the insulating composition.

The oligomer of phenyl methane maleimide may configure a network with the liquid crystal oligomer and the 4-functional bisphenol F type epoxy resin and exhibit a synergic effect, thereby improving thermal properties. As described above, the insulating composition may form varnish by mixing a solvent so that a viscosity of the varnish is 1000 to 2000 cps.

The insulating composition according to the preferred embodiment of the present invention may further contain an inorganic filler, a curing agent, a curing accelerator, and an initiator.

The inorganic filler may be contained in the insulating composition in order to decrease the CTE, and a content of the inorganic filler in the resin composition may be changed according to the desired properties in consideration of uses of the resin composition, but may be 50 to 80 weight % based on 100 weight % of the insulating composition. When the content of the inorganic filler is less than 50 weight %, the CTE may be increased, and when the content is more than 80 weight %, adhesion strength may be decreased.

The inorganic filler used in the present invention may be one or a combination of at least two of silica (SiO₂), alumina (Al₂O₃), silicon carbide (SiC), barium sulfate (BaSO₄), talc, mica powder, aluminum hydroxide (AlOH₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃), calcium zirconate (CaZrO₃). Here, in the case in which the insulating composition contains the inorganic filler, the insulating composition may be formed so that the viscosity of varnish is 700 to 1500 cps.

In addition, the curing agent may be contained at a content of 0.05 to 0.2 weight % based on 100 weight % of the resin composition and be at least one selected from an amine based curing agent, an acid anhydride based curing agent, a polyamine curing agent, a polysulfide curing agent, a phenol novolac type curing agent, a bisphenol A type curing agent, and dicyandiamide curing agent.

Again, referring to FIGS. 1 and 2A, the insulating composition prepared as described above is coated on the carrier film 150. Here, the carrier film 150 may be formed using any one selected from Teflon, polyimide, polyethylene terephthalate (PET), and a combination thereof. In this case, the coating of the insulating composition may be repeated at least two times on the carrier film 150 by any one method selected from a spray coating method, a dip coating method, a spin coating method, and a gravure coating method.

The insulating composition is coated on the carrier film 150 as described above and then dried. In this case, the insulating layer 110 may be formed by drying the insulating composition at 10 to 150° C. for 3 to 180 minutes. For example, the insulating composition may be dried at 100 to 120° C. for 10 to 30 minutes, and the dried insulating composition may form the insulating layer 110 having a viscosity of 500 to 1000 cps. As described above, the carrier substrate 10 in which the insulating layer 110 is formed on the carrier film 150 may be formed by drying the insulating composition. Here, a thickness of the insulating layer 110 may be controlled by adjusting a coating time or a coating amount.

As shown in FIGS. 1 and 2B, after the carrier substrate 10 including the insulating layer 110 is formed by drying the insulating composition on the carrier film 150, forming first and second carrier substrates 10a and 10b is performed. Here, two carrier substrates 10 are prepared, and glass fiber 200 is proved between the two carrier substrates 10, such that the two carrier substrates 10 may be laminated.

In this case, the carrier substrate 10 disposed on an upper portion is referred to as the first carrier substrate 10a, and the carrier substrate 10 disposed on a lower portion is referred to as the second carrier substrate 10b, having the glass fiber 200 therebetween. In addition, the insulating layer 110 formed on the first carrier substrate 10a is referred to as a first insulating layer 110a, and the insulating layer 110 formed on the second carrier substrate 10b is referred to as a second insulating layer 110b.

According to the preferred embodiment of the present invention, the first and second insulating layers 110a and 110b may be controlled so as to have a thickness equal to or different from each other. That is, the first and second insulating layers 110a and 110b may be formed under the same conditions to thereby have the same thickness, or be formed so as to have different thicknesses from each other by changing the coating amount and the coating time.

Meanwhile, the glass fiber 200 may be interposed between the first and second insulating layers 110a and 110b. As the glass fiber 200, at least one selected from a group consisting of E-glass fiber, T-glass fiber, U-glass fiber, quarts fiber textiles, and aramid fiber textiles may be used. In addition, an organic fiber or inorganic fiber may be used in addition to the glass fiber, wherein as the organic fiber and inorganic fiber, at least one material selected from glass fiber, carbon fiber, polyparaphenylenebenzobisoxazole fiber, thermotropic liquid crystalline polymer fiber, lyotropic liquid crystalline polymer fiber, aramid fiber, polypyridobisimidazole fiber, polybenzotiazole fiber, and polyacrylate fiber may be used.

Referring to FIGS. 1 and 2C, a laminated substrate 5 may be formed by bonding the first and second carrier substrates 10a and 10b. The forming of the laminated substrate 5 may be performed by laminating the first and second carrier substrates 10a and 10b in a degree of vacuum of 5 to 15 torr at 80 to 100° C. and a pressure of 0.42 to 0.48 MPa for 10 to 30 seconds.

Referring to FIGS. 1 and 2D, pressing the laminated substrate 5 may be performed. In the pressing of the laminated substrate 5, the laminated substrate 5 is pressed in a degree of vacuum of 5 to 15 torr at 80 to 100° C. and a pressure of 0.45 to 0.51 MPa for 30 to 50 seconds.

Here, the pressing may be performed by a batch method or a roll press method. When the pressing is performed by the batch method, the pressing may be performed at a surface pressure of 0.1 to 50 MPa. When the pressing is performed by the roll press method, a laminated substrate may be pressed at a nip press of 1 to 500 kgf/cm. Although the batch method is shown by way of example in the drawing, the roll press method may be advantageous for mass-production.

Referring to FIGS. 1 and 2E, a prepreg 1 may be formed by removing the carrier film 150 from a laminated substrate 5 subjected to the pressing. In this case, the prepreg 1 may be formed so as to have a thickness of 10 to 200 μm. In addition, the prepreg 1 may be symmetrically or asymmetrically formed and have a coefficient of thermal expansion of 9 to 12 ppm/° C. Further, a printed circuit board may be formed by laminating a buildup layer on the prepreg 1.

As described above, the prepreg 1 may be formed as a thin plate by laminating the first and second carrier substrates 10a and 10b and pressing the laminated substrates, and thickness quality of the prepreg 1 may be stabilized. In addition, the prepreg contains the liquid crystal oligomer, such that the prepreg may correspond to thermal expansion, and since arrangement of the glass fiber 200 impregnated into the prepreg 1 may be asymmetrically or symmetrically adjusted in the insulating layer 110, such that thermal expansion properties may be improved.

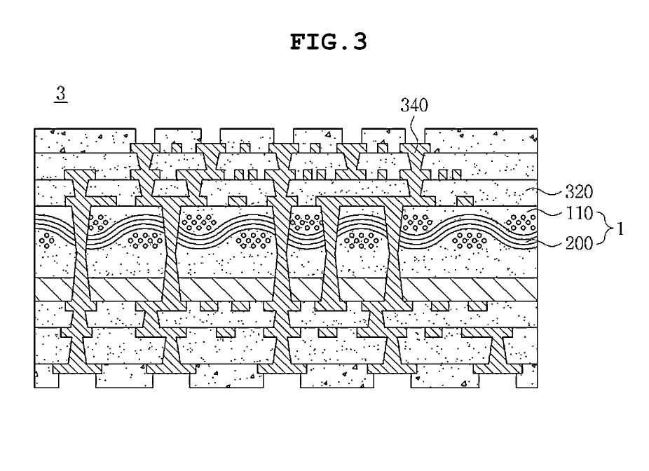

FIG. 3 is a cross-sectional view showing a printed circuit board including a prepreg according to another preferred embodiment of the present invention. Here, in order to avoid an overlapped description, the description will be provided, based on FIGS. 1 to 2F.

Referring to FIG. 3, a printed circuit board 3 including the prepreg 1 according to another preferred embodiment of the present invention may include the prepreg 1 and a buildup layer formed on the prepreg 1.

The prepreg 1 may be disposed at the center of the printed circuit board 3 to serve as a core layer. The buildup layer is formed on an upper or lower surface of the prepreg 1.

The buildup layer may include an insulating layer 320 disposed on at least one of the upper and lower surfaces of the prepreg 1 and a circuit layer 340 disposed on the insulating layer 320 and connecting between layers. The circuit layer 340 may be a circuit connected to an electronic component.

Here, the prepreg 1 and the insulating layer 320 may serve to insulate the circuit layers 340 from each other or to insulate the electronic components from each other and simultaneously serve as a structural material for maintaining rigidity of a package. In this case, in the insulating composition configuring the prepreg 1 in the printed circuit board 3, various properties such as the coefficient of thermal expansion, the glass transition temperature, uniformity of thickness, and the like, are required. Particularly, in accordance with the recent trend toward thinness, the prepreg should be manufactured so as to have a thinner thickness. In addition, as the thickness of prepreg 1 becomes thin, as thickness quality of the board may be unstable, such that properties such as the coefficient of thermal expansion, a dielectric constant, a dielectric loss, or the like, may be deteriorated, and a warpage phenomenon at the time of mounting the components and a signal transmission defect in a high frequency region may be generated. Further, when wiring density of the printed circuit board 3 is increased, heat generated in the printed circuit board 3 may cause thermal expansion of the printed circuit board 3. Warpage of the printed circuit board 3 may be generated due to this heat according to a formation area of the circuit layer 340 having high thermal conductivity.

However, in the prepreg 1 for a printed circuit board according to the preferred embodiment of the present invention, since the glass fiber may be symmetrically or asymmetrically formed so as to correspond to the formation area of the circuit layer 340, the coefficient of thermal expansion property of the printed circuit board 3 may be improved, and the warpage defect of the printed circuit board 3 may be decreased.

Hereinafter, the present invention will be described with reference to Examples and Comparative Examples in detail, but the present invention is not limited thereto.

### Example

### Preparation of Liquid Crystal Oligomer

218.26 g of 4-aminophenol (2.0 mol), 415.33 g of isophthalic acid (2.5 mol), 276.24 g of 4-hydroxy benzoic acid (2.0 mol), 282.27 g of 6-hydroxy-2-naphthoic acid (1.5 mol), 648.54 g of 9,10-dihydroxy-9-oxa-10-phosphaphenanthrene-10-oxide (DOPO-HQ, 2.0 mol), and 1531.35 g of acetic anhydride (15.0 mol) were added in a 10 to 20 L glass reactor. After the atmosphere in the glass reactor was sufficiently substituted with nitrogen gas, a temperature in the reactor was raised to about 230° C. under nitrogen gas flow, and the mixture was refluxed for about 4 hours while maintaining the temperature in the reactor at about 230° C. Then, 188.18 g of 6-hydroxy-2-naphthoic acid (1.0 mol) for end capping was additionally added thereto, followed by removing acetic acid and unreacted acetic anhydride, which were residual products, thereby preparing a liquid crystal oligomer. The liquid crystal oligomer having a viscosity of 800 to 1000 cps and a number average molecular weight of 3500 to 5000 was used.

Preparation of Insulating Composition

In 28.12 g of N,N′-dimethylacetamide (DMAc) solvent, an insulating composition composed of 12% of the liquid crystal oligomer (LCO), 16% of 4-functional bisphenol F type epoxy resin, 12% of bismaleimide, 0.16% of dicyandiamide as a curing agent, and 60% of silica as an inorganic filler was prepared. Here, the epoxy resin having a viscosity of 20000 cps was used. In addition, a content of the solvent was adjusted at 30 to 70% in consideration of a viscosity of varnish so that the varnish had a viscosity of 1000 to 2000 cps.

Manufacturing of Carrier Substrate

A PET film was used as a carrier film, and the insulating composition was spin-coated on the PET film. In this case, the viscosity of the insulating composition was 500 to 1000 cps at room temperature (measured using a Brookfield viscometer at 20 to 25° C. and 100 rpm), a drying temperature was 110° C., and a drying time was 20 minutes. A carrier substrate was formed by drying the insulating composition as described above.

Manufacturing of Prepreg

Two carrier substrates were manufactured. Glass fiber was prepared and laminated between the two carrier substrates, thereby forming a laminated substrate. That is, in the laminated substrate, the carrier film/the insulating layer/the glass fiber/the insulating layer/the carrier film were sequentially laminated. Here, in order to manufacture the laminated film, lamination was repeated at least two times under conditions of a lamination temperature of 90° C., a lamination pressure of 0.45 MPa, a lamination time of 20 seconds, and a degree of vacuum of 10 torr, thereby forming the laminated substrate.

The laminated substrate was repeatedly pressured at least two times under the conditions of a lamination temperature of 90° C., a lamination pressure of 0.48 MPa, a lamination time of 40 seconds, and a degree of vacuum of 10 torr, thereby curing the insulating composition. After the laminated substrate was pressed, the PET film used as the carrier substrate was separated therefrom, thereby forming the prepreg.

### Comparative Example

### Manufacturing of Prepreg

The liquid crystal oligomer was excluded from the insulating composition prepared in Example, thereby forming an insulating composition. An epoxy based resin was further added at the same content as that of the liquid crystal oligomer. Other manufacturing methods were the same as those in Example. The insulating composition formed as described above was put into an impregnation bath, and the glass fiber was dipped into the impregnation bath, thereby coating the insulating composition on the glass fiber. Then, the insulating composition coated on the glass fiber was moved to a drying unit, and the prepreg was manufactured by hot wind or ultraviolet light in the drying unit.

Measurement of Physical Property

Physical properties of the prepreg manufactured in Example and Comparative Example were evaluated, and the results were shown in the following Table 1. The coefficient of thermal expansion was measured and evaluated in a temperature range of 50 to 100° C. using a thermo mechanical analyzer (TMA) and thermo mechanical analysis was performed by a tensile force weighted method. After a sample was mounted on the TMA, measurement was performed at a heating rate of 5° C./min. At the time of measuring the coefficient of thermal expansion (α1, Tg or less), an average linear thermal expansion rate (ppm) at 50 to 100° C. was calculated.

The physical properties of the insulating film manufactured in Example and Comparative Example were evaluated, and the results were shown in the following Table 1.

TABLE 1

| Sample | Coefficient of thermal expansion (ppm/° C.) |
|---|---|
| Comparative Example | 11.6 |
| Example | 10.3 |

As shown in Table 1, it may be appreciated that the coefficient of thermal expansion was more excellent in the Example as compared to the Comparative Example. In the Comparative Example, the coefficient of thermal expansion was 11.6 ppm/° C., but in the Example, the coefficient of thermal expansion was 10.3 ppm/° C.

Describing the Comparative Example and the Example in detail, in the Comparative Example, the prepreg was formed by a general impregnation method, such that the insulating layers were formed at a predetermined thickness, having the glass fiber therebetween. On the other hand, in the Example, the glass fiber may be asymmetrically or symmetrically formed with respect to the thickness of the insulating layer, and in the Example, the prepreg was asymmetrically formed.

It may be judged that in the Example, the liquid crystal oligomer was contained, which improved heat resistance property, such that the coefficient of thermal expansion property was improved. Further, at the time of applying the prepreg in the Example to a printed circuit board, in the case of disposing the prepreg according to the present invention so as to correspond to a formation area of circuit layers formed on upper and lower portions of the printed circuit board, the coefficient of thermal expansion property may be further improved. In addition, a formation thickness may be thinned as compared to the case of curing the insulating composition using hot wind or ultraviolet ray to form the prepreg. The reason is that since the prepreg is formed by pressing, the thickness of the prepreg may be adjusted.

As described above, according to the present invention, the prepreg for a printed circuit board may be manufactured as a thin plate, and the prepreg may be manufactured so as to have the desired thickness or maintain a uniform thickness, such that the thickness quality may be stabilized. In addition, the prepreg having a symmetric or asymmetric thickness at both sides based on the glass fiber may be manufactured, such that the prepreg may be widely applied to the board.

With the prepreg for a printed circuit board, the manufacturing method thereof, and printed circuit board including the same according to the preferred embodiment of the present invention, the prepreg for a printed circuit board may be manufactured as the thin plate, and the prepreg may be manufactured so as to have the desired thickness or maintain the uniform thickness, such that the thickness quality may be stabilized, and the coefficient of thermal expansion property may be improved.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A manufacturing method of a prepreg for a printed circuit board, the manufacturing method including:
coating an insulating composition on each of the two carrier films to form an insulating layer and drying the coated insulating composition to form first and second carrier substrates;
disposing glass fiber between the insulating layers of the first and second carrier substrates and bonding the first and second carrier substrates to each other to form a laminated substrate;
pressing the laminated substrate; and
removing the carrier film from the laminated substrate subjected to the pressing.

2. The manufacturing method as set forth in claim 1, wherein the insulating composition contains bismaleimide, a 4-functional bisphenol F type epoxy resin, and a liquid crystal oligomer.

3. The manufacturing method as set forth in claim 2, wherein the insulating composition contains 10 to 30 weight % of the liquid crystal oligomer, 5 to 20 weight % of bismaleimide, and 5 to 20 weight % of the 4-functional bisphenol F type epoxy resin.

4. The manufacturing method as set forth in claim 2, wherein the liquid crystal oligomer is represented by the following Chemical Formula 1, 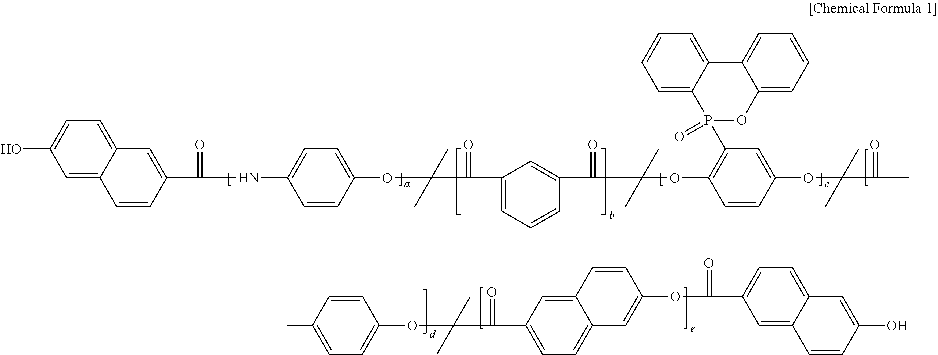
where, a is an integer of 13 to 26, b is an integer of 13 to 26, c is an integer of 9 to 21, d is an integer of 10 to 30, and e is an integer of 10 to 30.

5. The manufacturing method as set forth in claim 2, wherein the 4-functional bisphenol F type epoxy resin is N,N,N′,N′-tetraglycidyl-4,4′-methylene bisbenzenamine represented by the following Chemical Formula 2.

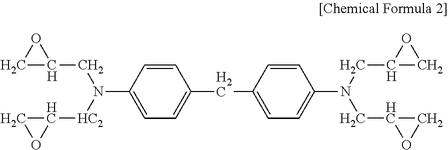

6. The manufacturing method as set forth in claim 2, wherein the bismaleimide resin is an oligomer of phenyl methane maleimide represented by the following Chemical Formula 3, 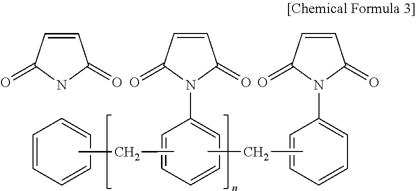
where, n is an integer of 1 or 2.

7. The manufacturing method as set forth in claim 1, wherein the insulating composition further contains an inorganic filler, a curing agent, a curing accelerator, and an initiator.

8. The manufacturing method as set forth in claim 7, wherein the inorganic filler is contained at a content of 50 to 80 weight % based on 100 weight % of the insulating composition and is one of silica (SiO₂), alumina (Al₂O₃), silicon carbide (SiC), barium sulfate (BaSO₄), talc, mica powder, aluminum hydroxide (AlOH₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃), calcium zirconate (CaZrO₃), and a combination thereof.

9. The manufacturing method as set forth in claim 7, wherein the curing agent is contained at a content of 0.05 to 0.2 weight % based on 100 weight % of the resin composition and is at least one selected from an amine based curing agent, an acid anhydride based curing agent, a polyamine curing agent, a polysulfide curing agent, a phenol novolac type curing agent, a bisphenol A type curing agent, and dicyandiamide curing agent.

10. The manufacturing method as set forth in claim 2, wherein the liquid crystal oligomer has a number average molecular weight of 3000 to 6000.

11. The manufacturing method as set forth in claim 1, wherein the carrier film is made of any one selected from Teflon, polyimide, polyethylene terephthalate (PET), and a combination thereof.

12. The manufacturing method as set forth in claim 1, wherein the first and second insulating layers are formed by performing the coating at least two times on the carrier film by any one method selected from a spray coating method, a dip coating method, a spin coating method, and a gravure coating method.

13. The manufacturing method as set forth in claim 1, wherein in the drying of the insulating composition, the insulating composition is dried at 10 to 150° C. for 3 to 180 minutes.

14. The manufacturing method as set forth in claim 1, wherein the insulating layer includes:
a first insulating layer formed on the first carrier substrate; and
a second insulating layer formed on the second carrier substrate;
the first and second insulating layers having thicknesses equal to or different from each other.

15. The manufacturing method as set forth in claim 1, wherein the glass fiber is at least one selected from a group consisting of E-glass fiber, T-glass fiber, U-glass fiber, quarts fiber textiles, and aramid fiber textiles.

16. The manufacturing method as set forth in claim 1, wherein in the pressing of the laminated substrate, the laminated substrate is pressed at 10⁻⁵ to 15 torr and 10 to 250° C. for 10 seconds to 5 hours.

17. The manufacturing method as set forth in claim 1, wherein the pressing of the laminated substrate is performed by any one method of a batch method and a roll press method.

18. The manufacturing method as set forth in claim 17, wherein in the pressing of the laminated substrate, the laminated substrate is pressed at a surface pressure of 0.1 to 50 Mpa.

19. The manufacturing method as set forth in claim 17, wherein in the pressing of the laminated substrate, the laminated substrate is pressed at a nip pressure of 1 to 500 kgf/cm.

20. A prepreg for a printed circuit board manufactured by the manufacturing method as set forth in claim 1.

21. The prepreg for a printed circuit board as set forth in claim 20, wherein it has a thickness of 10 to 200 μm.

22. The prepreg for a printed circuit board as set forth in claim 20, wherein it has a coefficient of thermal expansion of 9 to 12 ppm/° C.

23. A printed circuit board comprising:
the prepreg as set forth in claim 20; and
a buildup layer formed on an insulating layer of the prepreg.
